(19) United States
(12) Patent Application Publication
(10) Pub. No.: US 2024/0381610 A1
(43) Pub. Date: Nov. 14, 2024

(54) INTEGRATED CIRCUIT DEVICE AND MANUFACTURING METHOD THEREOF

(71) Applicant: TAIWAN SEMICONDUCTOR MANUFACTURING COMPANY, LTD., Hsinchu (TW)

(72) Inventors: Cheng-Yin WANG, Taipei City (TW); Wei-Xiang YOU, Kaohsiung City (TW); Kao-Cheng LIN, Taipei City (TW); Jui-Chien HUANG, Hsinchu City (TW); Szuya LIAO, Hsinchu County (TW)

(73) Assignee: TAIWAN SEMICONDUCTOR MANUFACTURING COMPANY, LTD., Hsinchu (TW)

(21) Appl. No.: 18/315,388

(22) Filed: May 10, 2023

(51) Int. Cl. H10B 10/00

(52) U.S. Cl. CPC H10B 10/125

(57) ABSTRACT

The first semiconductor layer and the second semiconductor layer are above the first semiconductor layer, in which the first and second semiconductor layers are vertically spaced apart from each other. The first and second source/drain epitaxial features are respectively on first and second sides of the first semiconductor layer. The third and fourth source/drain epitaxial features are respectively on first and second sides of the second semiconductor layer and above the first source/drain epitaxial feature. The first, third, and fourth source/drain epitaxial features have a first conductive type, and the second source/drain epitaxial feature has a second conductive type opposite to the first conductive type.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a circuit diagram of a static random access memory (SRAM) cell in accordance with some embodiments of the present disclosure.

FIGS. 2A and 2B are layouts of an integrated circuit device in accordance with some embodiments of the present disclosure.

FIGS. 3-20B illustrate schematic views of intermediate stages in the manufacture of an integrated circuit device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” may mean within 20 percent, or within 10 percent, or within 5 percent of a given value or range. One skilled in the art will realize, however, that the value or range recited throughout the description are merely examples, and may be reduced with the down-scaling of the integrated circuits. Numerical quantities given herein are approximate, meaning that the term “around,” “about,” “approximately,” or “substantially” can be inferred if not expressly stated.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The term “multi-gate device” is used to describe a device (e.g., a semiconductor transistor) that has at least some gate material disposed on multiple sides of at least one channel of the device. In some examples, the multi-gate device may be referred to as a gate all around (GAA) device or a nanosheet device having gate material disposed on at least four sides of at least one channel of the device. The channel region may be referred to as a “nanowire,” which as used herein includes channel regions of various geometries (e.g., cylindrical, bar-shaped) and various dimensions. In some examples, the multi-gate device may be referred to as a FinFET device. However, one of ordinary skill would recognize that the teaching can apply to a single channel (e.g., single nanosheet) or any number of channels. One of ordinary skill may recognize other examples of semiconductor devices that may benefit from aspects of the present disclosure.

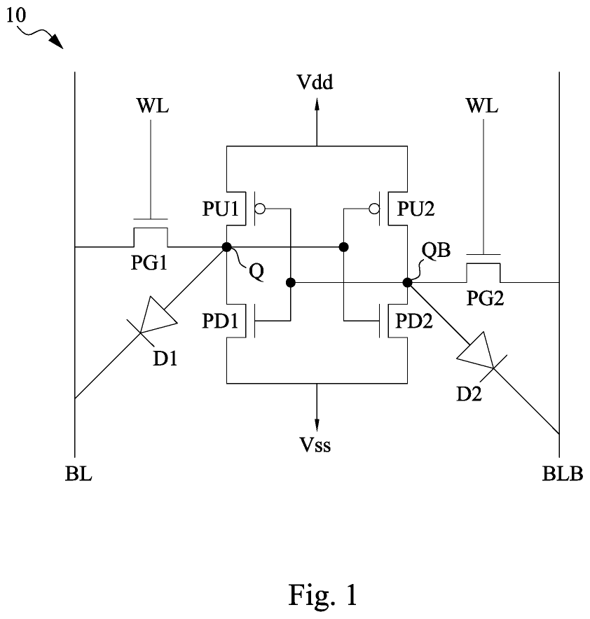

FIG. 1 is a circuit diagram of a static random access memory (SRAM) cell 10 in accordance with some embodiments of the present disclosure. SRAM cell 10 includes pull-up transistors PU1 and PU2, which are p-type Metal-Oxide-Semiconductor (PMOS) transistors, and pull-down transistors PD1 and PD2 and pass-gate transistors PG1 and PG2, which are n-type Metal-Oxide-Semiconductor (NMOS) transistors. The gates of pass-gate transistors PG1 and PG2 are controlled by a word line WL that determines whether SRAM cell 10 is selected or not. A latch formed of pull-up transistors PU1 and PU2 and pull-down transistors PD1 and PD2 stores a bit, wherein the complementary values of the bit are stored in storage data node Q and storage data node QB. The stored bit can be written into, or read from, SRAM cell 10 through complementary bit lines including bit line BL and bit line BLB. SRAM cell 10 is powered through a positive power supply node Vdd that has a positive power supply voltage. SRAM cell 10 is also connected to a power supply voltage node Vss, which may be an electrical ground. Transistors PU1 and PD1 form a first inverter. Transistors PU2 and PD2 form a second inverter. The first and second inverters are cross-latched. For example, the input of the first inverter (e.g., gates of the transistors PU1 and PD1) is connected to the output of the second inverter (e.g., drains of the transistors PU2 and PD2), and the output of the first inverter (e.g., drains of the transistors PU1 and PD1) is connected to the input of the second inverter (e.g., gates of the transistors PU2 and PD2). The input of the first inverter is also connected to the transistor PG2. The output of the first inverter is also connected to the transistor PG1.

The sources of pull-up transistors PU1 and PU2 are connected to positive power supply node Vdd. The sources of pull-down transistors PD1 and PD2 are connected to the power supply voltage node Vss. The gates of transistors PU1 and PD1 are connected to the drains of transistors PU2 and PD2, which form a connection node that is referred to as storage data node QB. The gates of transistors PU2 and PD2 are connected to the drains of transistors PU1 and PD1, which connection node is referred to as storage data node Q. A source/drain region of pass-gate transistor PG1 is connected to bit line BL. A source/drain region of pass-gate transistor PG2 is connected to bit line BLB.

In some embodiments of the present disclosure, diodes D1 and D2 are added to the circuit diagram of the cell 10. The configuration of the diode D2 can increase a current from the storage data node QB to the bit line BLB during a writing operation, thereby improving CFET SRAM writability.

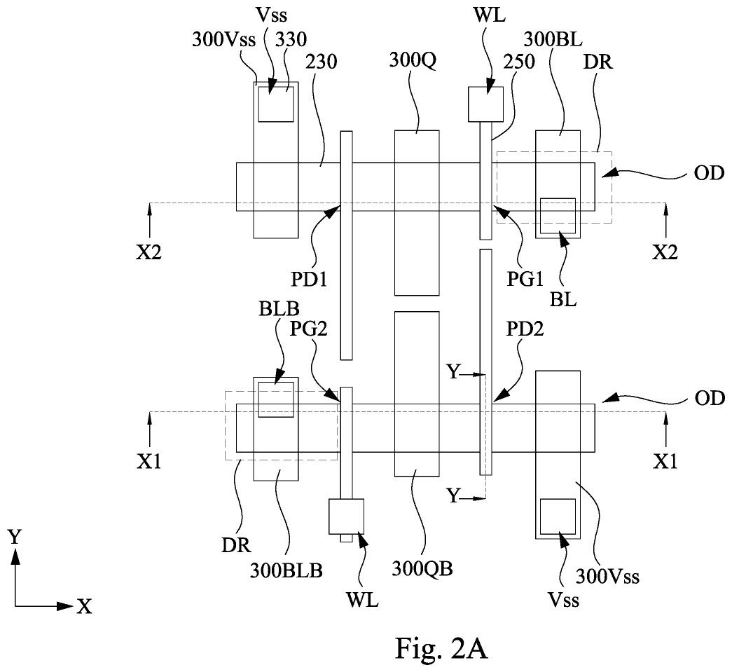

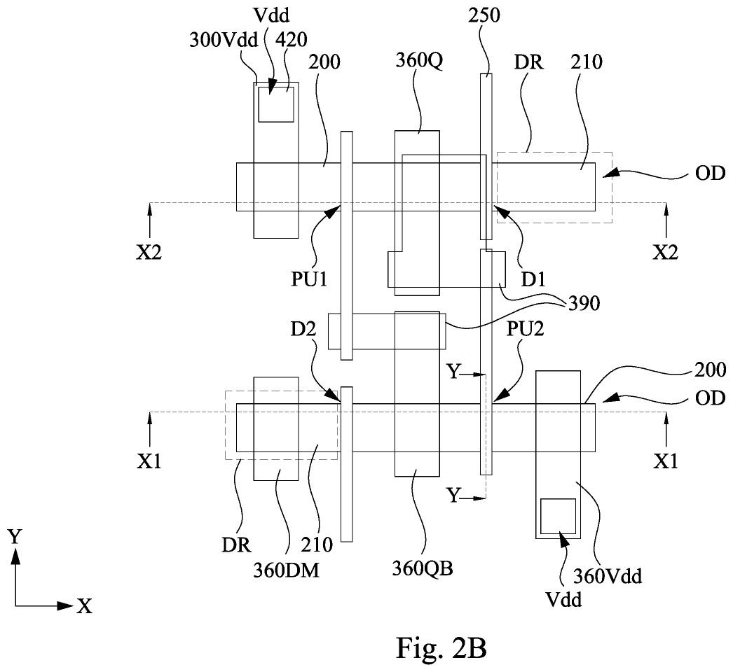

FIGS. 2A and 2B are layouts of an integrated circuit device in accordance with some embodiments of the present disclosure. In some embodiments, the integrated circuit device includes a 6T SRAM cell. For example, pull-up transistors PU1 and PU2, pull-down transistors PD1 and PD2, and pass-gate transistors PG1 and PG2 are illustrated in FIG. 2A. FIG. 2A illustrates layouts of active regions OD, gate structures 250, frontside contact plugs 300Vss, 300Q, 300QB, 300BL, 300BLB, and frontside conductive vias 330. The frontside conductive vias 330 are electrically connected to the bit line BL, the bit line BLB, word lines WL, and the power supply voltage node Vss, respectively. FIG. 2B illustrates layouts of active regions OD, gate structures 250, contact plugs 360Vdd, 360Q, 360QB, 360DM, and conductive vias 420 to the power supply voltage node Vdd. In the context, FIGS. 2A and 2B may also be considered as top views or plan views of the integrated circuit device.

In FIGS. 2A and 2B, the active regions OD may include channel regions surrounded by the gate structures 250, source/drain epitaxial structures 230 in FIG. 2A and source/drain epitaxial structures 200 and 210 in FIG. 2B. In the present embodiments, the source/drain epitaxial structures 230 in FIG. 2A are vertically overlapping with the source/drain epitaxial structures 200 and 210 in FIG. 2B. The source/drain epitaxial structures 230 and 210 are doped to have a same first conductive type, and the source/drain epitaxial structures 200 are doped to have a second conductive type opposite to the first conductive type. For example, in some embodiments, the source/drain epitaxial structures 230 and 210 are n-type source/drain epitaxial structures, and the source/drain epitaxial structures 200 are p-type source/drain epitaxial structures. In some alternative embodiments, the source/drain epitaxial structures 230 and 210 are p-type source/drain epitaxial structures, and the source/drain epitaxial structures 200 are n-type source/drain epitaxial structures. Reference is made to FIG. 1 and FIG. 2B, each of the diodes D1 and D2 can be formed by a source/drain epitaxial structure 200 and a source/drain epitaxial structure 210. The regions for the source/drain epitaxial structure 210 are denoted as regions DR in the context.

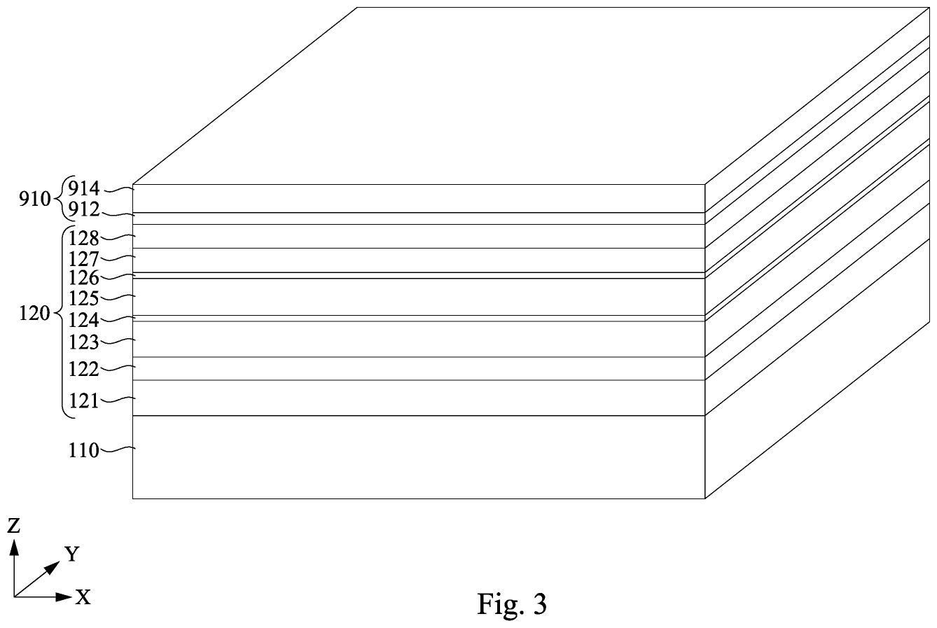

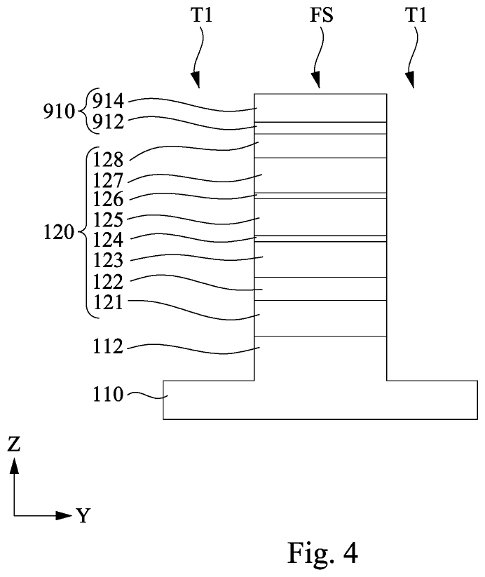

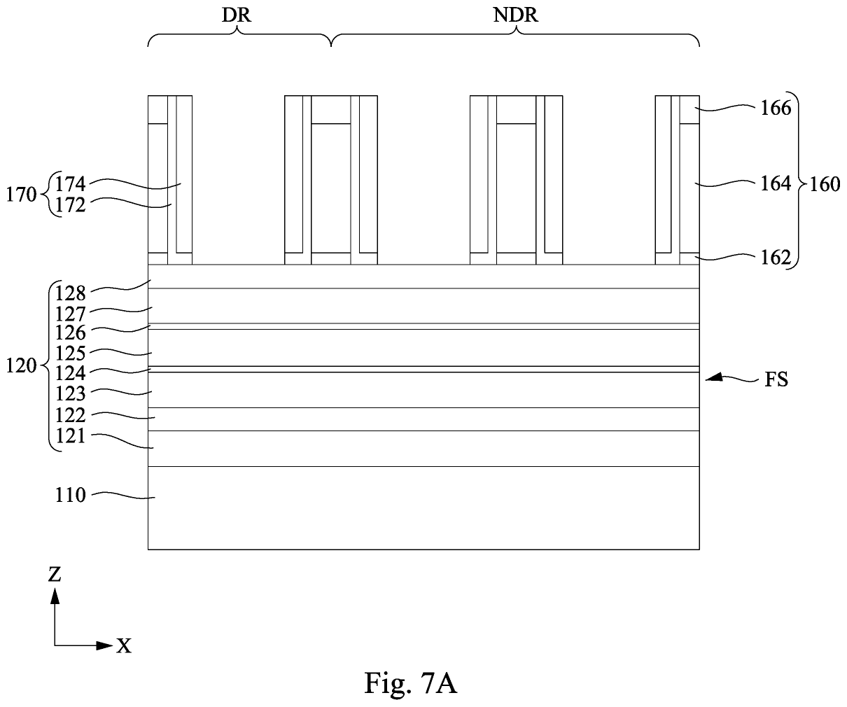

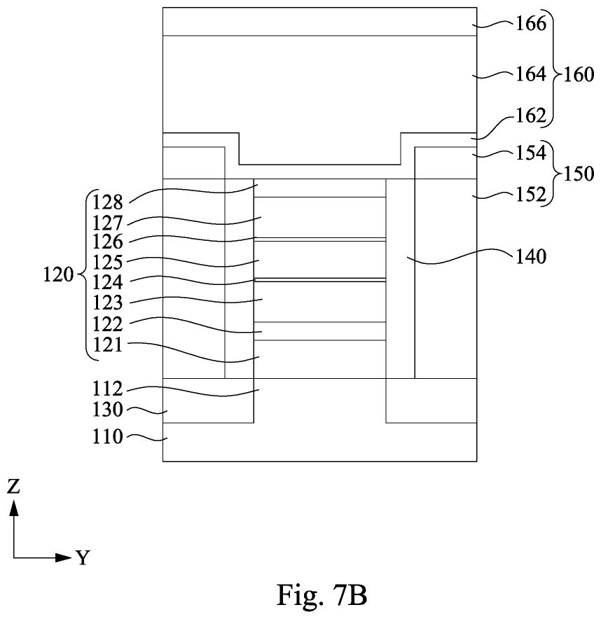

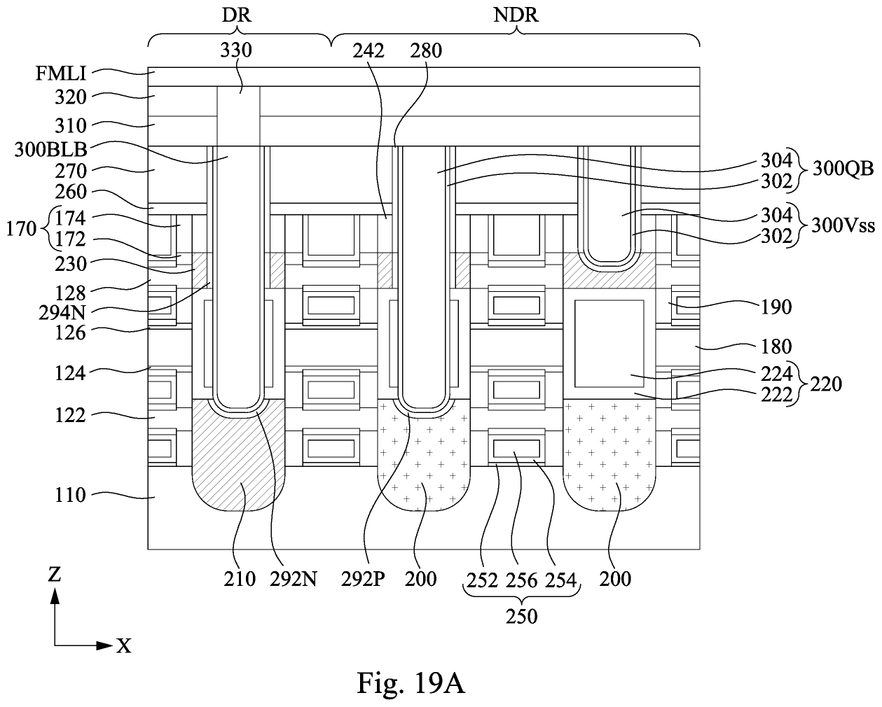

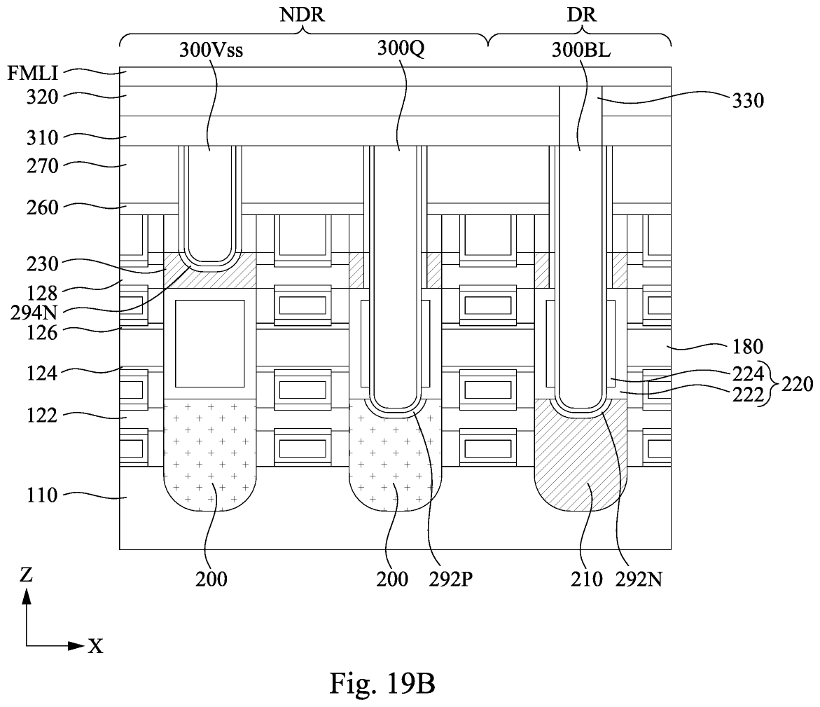

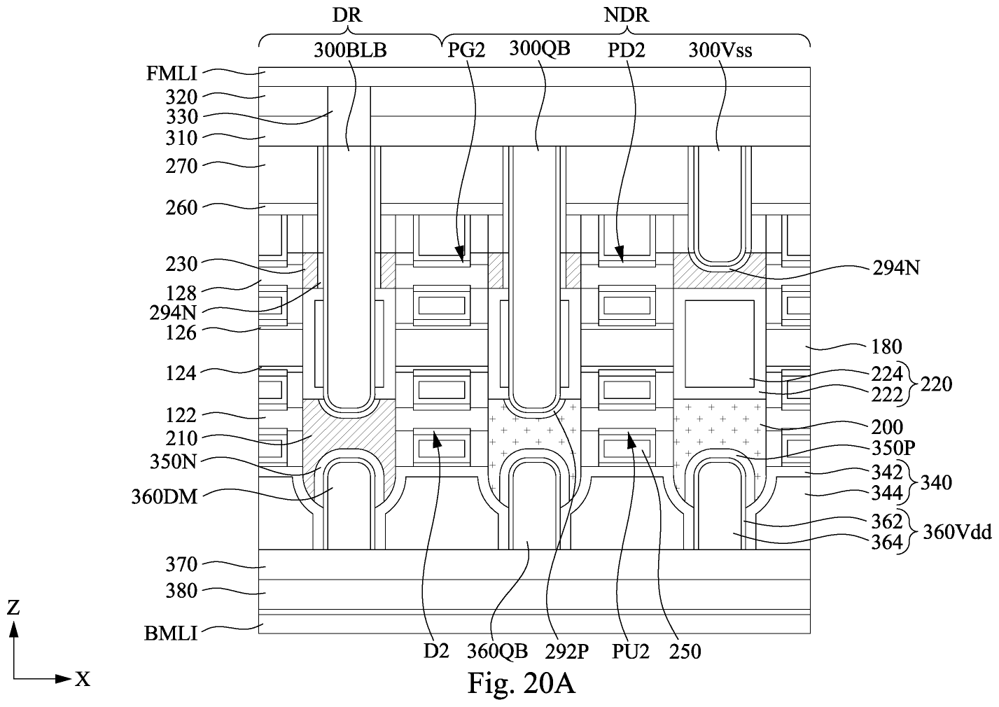

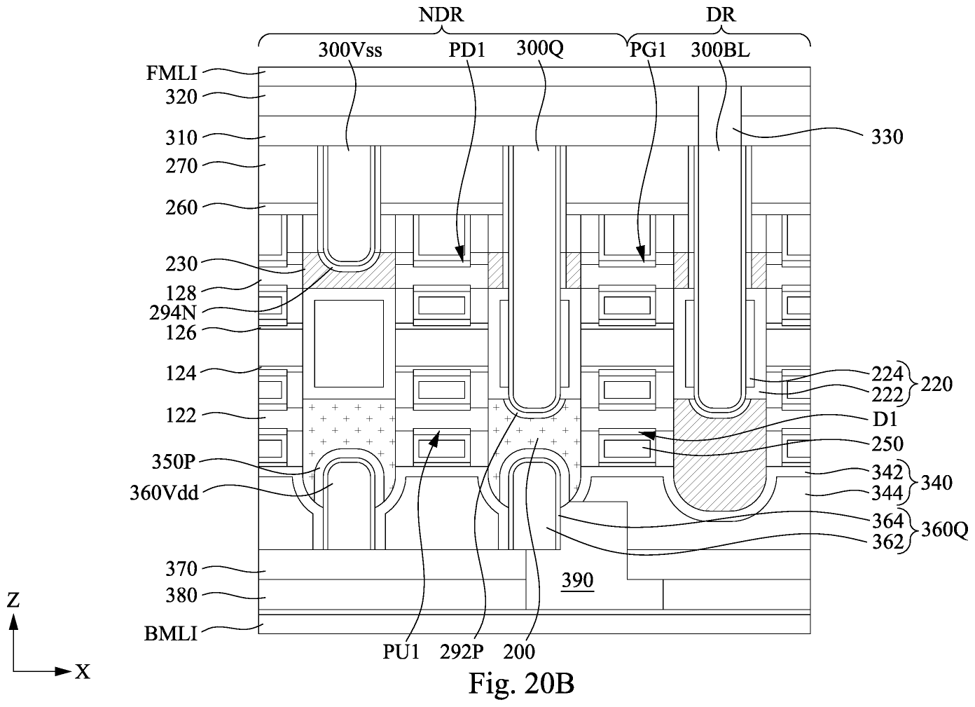

FIGS. 3-20B illustrate schematic views of intermediate stages in the manufacture of an integrated circuit device in accordance with some embodiments of the present disclosure. FIGS. 4, 5, 6, 7B, 17B, and 18B are cross-sectional views of the integrated circuit device (e.g., taken along line Y-Y in FIGS. 2A and 2B) at various manufacturing stages in accordance with some embodiments. FIGS. 7A, 8-18A, 19A, and 20A are cross-sectional views of the integrated circuit device (e.g., taken along line X1-X1 in FIGS. 2A and 2B) at various manufacturing stages in accordance with some embodiments. FIGS. 19B and 20B are cross-sectional views of the integrated circuit device (e.g., taken along line X2-X2 in FIGS. 2A and 2B) at various manufacturing stages in accordance with some embodiments. It is understood that additional steps may be provided before, during, and after the steps shown in FIGS. 3-20B, and some of the steps described below can be replaced or eliminated for additional embodiments of the method. The order of the operations/processes may be interchangeable.

Reference is made to FIG. 3. An epitaxial stack 120 is formed over a substrate 110. In some embodiments, the substrate 110 may include silicon (Si). Alternatively, the substrate 110 may include germanium (Ge), silicon germanium (SiGe), a III-V material (e.g., GaAs, GaP, GaAsP, AlInAs, AlGaAs, GaInAs, InAs, GaInP, InP, InSb, and/or GaInAsP; or a combination thereof) or other appropriate semiconductor materials. In some embodiments, the substrate 110 may include a semiconductor-on-insulator (SOI) structure such as a buried dielectric layer. Also, the substrate 110 may include a buried dielectric layer such as a buried oxide (BOX) layer, such as that formed by a method referred to as separation by implantation of oxygen (SIMOX) technology, wafer bonding, selective epitaxial growth (SEG), or another appropriate method.

The epitaxial stack 120 includes a sacrificial layer 121, a channel layer 122, a sacrificial layer 123, a semiconductor layer 124, an interlayer sacrificial layer 125, a semiconductor layer 126, a sacrificial layer 127, a channel layer 128 stacked in a sequence over the substrate 110. The sacrificial layers 121, 123, and 127 may have different semiconductor compositions from the channel layers 122 and 128 and the semiconductor layer 124 and 126. And, the interlayer sacrificial layer 125 may a different semiconductor composition from the layers 121-124 and 126-128. In some embodiments, the layers 121-128 may include SiGe with various semiconductor compositions. For example, a Si concentration in the sacrificial layers 121, 123, and 127 is less than a Si concentration in the channel layers 122 and 128 and the semiconductor layer 124 and 126, and greater than a Si concentration in the interlayer sacrificial layer 125. Stated differently, in the embodiments, a Ge concentration in the sacrificial layers 121, 123, and 127 is greater than a Ge concentration in the channel layers 122 and 128 and the semiconductor layer 124 and 126, and less than a Ge concentration in the interlayer sacrificial layer 125. For example, the channel layers 122 and 128 and the semiconductor layer 124 and 126 are SiₓGe₁₋ₓ, the sacrificial layers 121, 123, and 127 are Si_{y}Ge_{1-y}, the interlayer sacrificial layer 125 is Si_{z}Ge_{1-z}, in which x, y, z are in a range from 0 to 1, and x>y>z. However, other embodiments are possible including those that provide for the material/compositions having different oxidation rates and/or etch selectivity. In some embodiments where the sacrificial layers 121, 123, and 127 and the interlayer sacrificial layer 125 include SiGe and the channel layers 122 and 128 and the semiconductor layer 124 and 126 include Si, the Si oxidation rate of the channel layers 122 and 128 and the semiconductor layer 124 and 126 is less than the SiGe oxidation rate of the sacrificial layers 121, 123, and 127, and the SiGe oxidation rate of the sacrificial layers 121, 123, and 127 is less than the SiGe oxidation rate of the interlayer sacrificial layer 125.

The channel layers 122 and 128 or portions thereof may form nanosheet channel(s) of the multi-gate transistor. The term nanosheet is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. The channel layers 122 and 128 may be referred to as semiconductor channels in the context. The use of the channel layers 122 and 128 to define a channel or channels of a device is further discussed below.

By way of example, epitaxial growth of the layers of the stack 120 may be performed by a molecular beam epitaxy (MBE) process, a metalorganic chemical vapor deposition (MOCVD) process, and/or other suitable epitaxial growth processes. In some embodiments, the epitaxially grown layers such as, the channel layers 122 and 128 and the semiconductor layer 124 and 126 include suitable semiconductor material, such as like Si, Ge, Sn, SiGe, GeSn, III-V semiconductor, the like, or the combination thereof. In some embodiments, the channel layers 122 and 128 and the semiconductor layer 124 and 126 may include a same semiconductor material as that substrate 110. In some embodiments, the epitaxially grown sacrificial layers 121, 123, and 127 include a different material than the substrate 110, and the interlayer sacrificial layer 125 includes a different material than the substrate 110. For example, the sacrificial layers 121, 123, and 127 and the interlayer sacrificial layer 125 include suitable semiconductor material, such as Si, Ge, SiGe, GeSn, III-V semiconductor, the like, or the combination thereof. In some other embodiments, at least one of the layers 121-128 may include other materials such as a compound semiconductor such as silicon carbide, gallium arsenide, gallium phosphide, indium phosphide, indium arsenide, and/or indium antimonide, an alloy semiconductor such as GaAsP, AlInAs, AlGaAs, InGaAs, GaInP, and/or GaInAsP, or combinations thereof. As discussed, the materials of the layers 121-128 may be chosen based on providing differing oxidation and/or etching selectivity properties. In some embodiments, the layers 121-128 are intrinsic semiconductor layers, which are not intentionally doped, for example, not having intentionally placed dopants, but rather having a doping resulting from process contaminants. In some embodiments, the layers 121-128 are substantially dopant-free (i.e., having an extrinsic dopant concentration from about 0 cm⁻³ to about 1×10¹⁸ cm⁻³), where for example, no intentional doping is performed during the epitaxial growth process.

Reference is made to FIGS. 2A and 2B. A plurality of semiconductor fins FS extending from the substrate 110 are formed. The semiconductor fins FS may extend substantially along a direction X. In various embodiments, each of the fins FS includes a substrate portion 112 formed from the substrate 110 and portions of each of the epitaxial layers of the epitaxial stack 120 including epitaxial layers 121-128. The fins FS may be fabricated using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fins FS by etching initial epitaxial stack 120. The etching process can include dry etching, wet etching, reactive ion etching (RIE), and/or other suitable processes.

In the embodiments as illustrated in FIGS. 3 and 4, a hard mask (HM) layer 910 is formed over the epitaxial stack 120 prior to patterning the fins FS. In some embodiments, the HM layer 910 includes an oxide layer 912 (e.g., a pad oxide layer that may include SiO₂) and a nitride layer 914 (e.g., a pad nitride layer that may include Si₃N₄) formed over the oxide layer. The oxide layer 912 may act as an adhesion layer between the epitaxial stack 120 and the nitride layer 914 and may act as an etch stop layer for etching the nitride layer 914. In some examples, the HM oxide layer 912 includes thermally grown oxide, chemical vapor deposition (CVD)-deposited oxide, and/or atomic layer deposition (ALD)-deposited oxide. In some embodiments, the HM nitride layer 914 is deposited on the HM oxide layer 912 by CVD and/or other suitable techniques.

The fins FS may subsequently be fabricated using suitable processes including photolithography and etch processes. The photolithography process may include forming a photoresist layer (not shown) over the HM layer 130, exposing the photoresist to a pattern, performing post-exposure bake processes, and developing the resist to form a patterned mask including the resist. In some embodiments, patterning the resist to form the patterned mask element may be performed using an electron beam (e-beam) lithography process or an extreme ultraviolet (EUV) lithography process. The patterned mask may then be used to protect regions of the substrate 110, and layers formed thereupon, while an etch process forms trenches Tl in unprotected regions through the HM layer 910, through the epitaxial stack 120, and into the substrate 110, thereby leaving the plurality of extending fins FS. The trenches Tl may be etched using a dry etch (e.g., reactive ion etching), a wet etch, and/or combination thereof. Numerous other embodiments of methods to form the fins on the substrate may also be used including, for example, defining the fin region (e.g., by mask or isolation regions) and epitaxially growing the epitaxial stack 120 in the form of the fins FS.

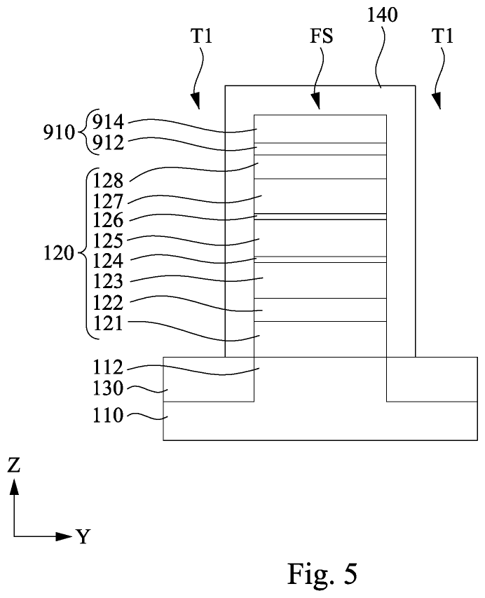

Reference is made to FIG. 5. An isolation structure 130 is formed in the trench Tl between the fins FS. The isolation structure 130 may be a single-layer or a multi-layer structure. In some embodiments, the isolation structure 130 includes low-k dielectric materials, SiN, SiCN, SiOC, SiOCN or the like. Formation of the isolation structure 130 may include depositing a dielectric material over the structure in FIG. 4, followed by an etching back process. Through the etching back process, a top surface of the isolation structure 130 may be level with or lower than a bottom surface of the epitaxial stack 120. In some alternatively embodiments, the top surface of the isolation structure 130 may be higher than the bottom surface of the epitaxial stack 120.

A cladding layer 140 is formed on opposite sides of the fins FS. In some embodiments, the cladding layer 140 includes a semiconductor material. In some embodiments, the cladding layer 140 grows on semiconductor materials but not on dielectric materials. For example, the cladding layer 140 includes SiGe and is grown on the Si of the epitaxial stack 120 not on the dielectric material of the isolation structure 130. In some embodiments, the cladding layer 140 may be formed by first forming a semiconductor layer on the isolation structure 130, and followed by an etch process to remove portions of the semiconductor layer formed on the isolation structure 130. In some embodiments, the cladding layer 140 have a semiconductor composition similar to that of the sacrificial layers 121, 123, and 127 for having the similar etch selectivity. For example, the cladding layer 140 and the first semiconductor layers 121, 123, and 127 are Si_{y}Ge_{1-y}, the channel layers 122 and 128 and the semiconductor layer 124 and 126 are SiₓGe₁₋ₓ, the interlayer sacrificial layer 125 is Si_{z}Ge_{1-z}, in which x, y, z are in a range from 0 to 1, and x>y>z. The cladding layer 140 and the first semiconductor layers 121, 123, and 127 may be removed subsequently to create space for the gate electrode layer.

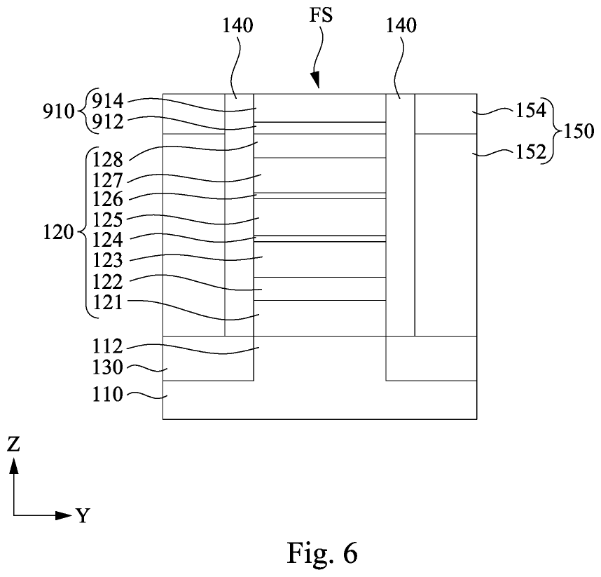

Reference is made to FIG. 6. A dielectric structure 150 is formed in the trench Tl between the fins FS. The dielectric structure 150 may include an isolation structure 152 and a high-k cap layer 154. The isolation structure 152 may be a single-layer or a multi-layer structure. In some embodiments, the isolation structure 152 includes suitable dielectric materials, such as low-k dielectric materials, SiN, SiCN, SiOC, SiOCN, the like, or the combination thereof. In some embodiments, the high-k cap layer 154 may include SiO, SiN, SiC, SiCN, SiON, SiOCN, AlO, AN, AlON, ZrO, ZrN, ZrAlO, HfO, the like, or the combination thereof. In some embodiments, the high-k cap layer 154 includes a high-k dielectric material (e.g., a material having a k value greater than 7).

Formation of the dielectric structure 150 may include depositing a dielectric material of the isolation structure 152 over the structure in FIG. 5, followed by an etching back process. Through the etching back process, a top surface of the isolation structure 152 may be recessed to be lower than a top surface of the HM layer 910. A high-k dielectric material is then deposited over the recessed top surface of the isolation structure 152. A planarization process (e.g., chemical mechanical polish (CMP) process) may be performed to remove an excess portion of the high-k dielectric material above a top surface of the HM layer 910. A remaining portion of the high-k dielectric material over the recessed top surface of the isolation structure 152 forms the high-k cap layer 154.

Reference is made to FIGS. 7A and 7B. The cladding layer 140 are recessed, and the HM layer 910 is removed. The recess of the cladding layer 140 may be performed by any suitable process, such as dry etch, wet etch, or a combination thereof. The recess process may be controlled so that the remaining cladding layer 140 are substantially at the same level as the top surface of the topmost epitaxial layer 128 in the epitaxial stack 120. The etch process may be a selective etch process that does not substantially remove the high-k cap layer 154. The removal of the HM layer 910 may be performed by any suitable process, such as dry etch, wet etch, or a combination thereof. The removal of the HM layer 910 exposes the top surfaces 804 of the topmost epitaxial layer 128 in the epitaxial stack 120.

One or more dummy gate structures 160 are formed on the epitaxial stack 120. The dummy gate structure 160 may include a gate dielectric 162, a gate electrode 164, and a hard mask 166. The gate dielectric 162 may include one or more layers of dielectric material, such as silicon oxide, silicon nitride, a high-k dielectric material, and/or other suitable dielectric material. In some embodiments, the gate electrode 164 includes a material different than that of the gate dielectric 162. In some embodiments, the gate dielectric 162 may be deposited by a CVD process, a sub-atmospheric CVD (SACVD) process, a FCVD process, an ALD process, a PVD process, or other suitable process. The gate electrode 164 may include polycrystalline silicon (polysilicon). The hard mask 166 may include a silicon oxide layer and a silicon nitride layer. In some embodiments, the materials of the dummy gate structures 160 are formed by various processes such as layer deposition, for example, CVD, PVD, ALD, thermal oxidation, or other suitable deposition techniques, or combinations thereof.

The dummy gate structures 160 may be formed by first depositing a blanket gate dielectric layer, a gate electrode layer, and a mask layer, followed by pattern and etch processes. For example, the pattern process includes a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etch (e.g., RIE), wet etch, other etch methods, and/or combinations thereof. By patterning the dielectric layer, the gate electrode layer, and the mask layer, the fins FS are partially exposed on opposite sides of the dummy gate structure 160.

Gate spacers 170 are formed on opposite sidewalls of the dummy gate structures 160. In some embodiments, the spacer 170 includes multiple layers, such as the layers 172 and 174. The layers 172 and 174 of the spacer 170 may be made of a dielectric material such as silicon oxide, silicon nitride, silicon carbide, silicon oxynitride, SiCN, silicon oxycarbide, SiOCN, and/or combinations thereof. The gate spacers 170 may be formed by first depositing one or more conformal spacer material layers and subsequently etching back the one or more spacer material layers to form gate spacers 170. The one or more conformal spacer material layers may be formed by ALD or CVD processes. The etching back process may include an anisotropic dry etch process. During the anisotropic dry etch process, most of the one or more spacer material layers are removed from horizontal surfaces, such as the tops of the fins FS, leaving the gate spacers 170 on the vertical surfaces, such as the sidewalls of the dummy gate structures 160.

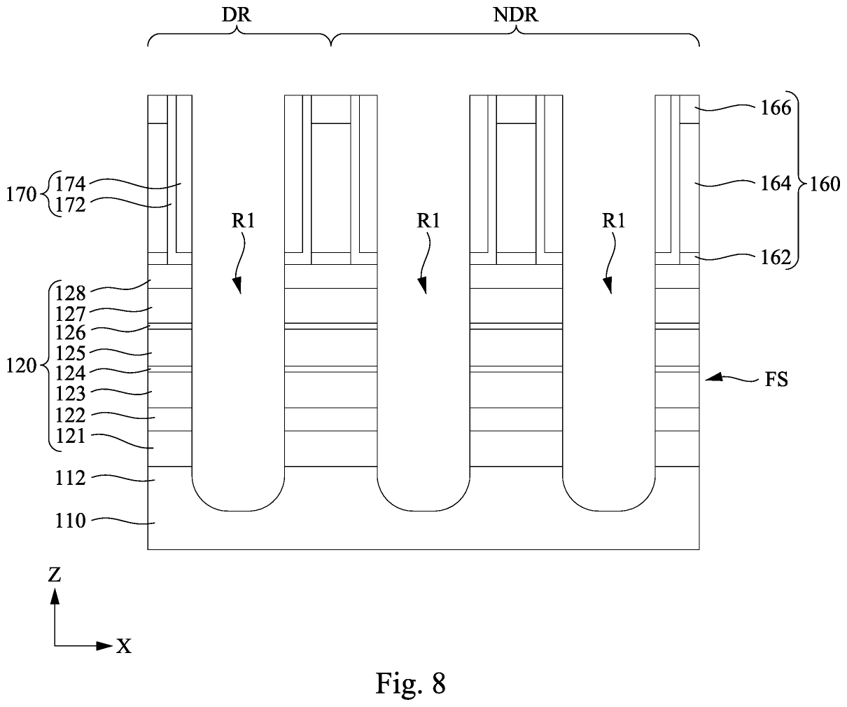

Reference is made to FIG. 8. Exposed portions of the semiconductor fins FS that extend laterally beyond the gate spacers 170 (e.g., in source/drain regions of the fins FS) are etched by using, for example, an anisotropic etching process that uses the dummy gate structures 160 and the gate spacers 170 as an etch mask, resulting in recesses R1 into the semiconductor fins FS and between corresponding dummy gate structures 160. The recesses R1 may extend through the epitaxial layers 121-128. After the anisotropic etching, end surfaces of the epitaxial layers 121-128 are exposed and aligned with respective outermost sidewalls of the gate spacers 170, due to the anisotropic etching. In some embodiments, the anisotropic etching may be performed by a dry chemical etch (e.g., reactive-ion etching) with a plasma source and a reaction gas. The plasma source may be an inductively coupled plasma (ICR) source, a transformer coupled plasma (TCP) source, an electron cyclotron resonance (ECR) source or the like, and the reaction gas may be, for example, a fluorine-based gas (such as SF₆, CH₂F₂, CH₃F, CHF₃, or the like), chloride-based gas (e.g., Cl₂), hydrogen bromide gas (HBr), oxygen gas (O₂), the like, or combinations thereof.

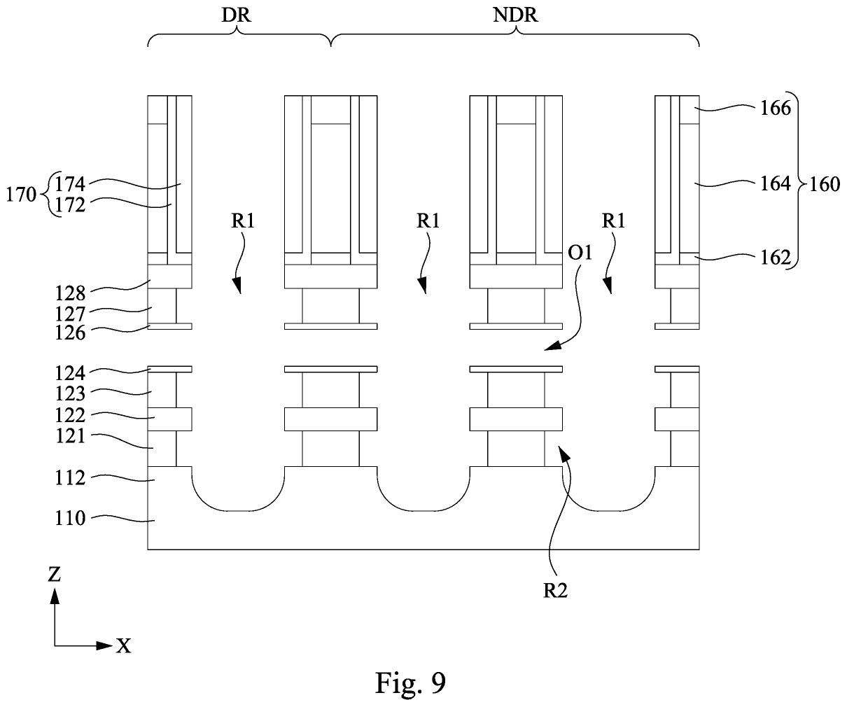

Reference is made to FIG. 9. The sacrificial layers 121, 123, and 127 are laterally or horizontally recessed by using suitable selective etching process, resulting in lateral/sidewall recesses R2 vertically between corresponding layers 122 and 124, and vertically between corresponding layers 126 and 128. For example, end surfaces of the sacrificial layers 121, 123, and 127 are recessed by the selective etching process. The various compositions in epitaxial layers result in different oxidation rates and/or etch selectivity, thereby facilitating the selective etching process. In some embodiments, a selective dry etching process is performed by using fluoride-based etchant gas, such as NF₃, SF₆, the like, or the combination thereof. The fluoride-based gas may etch SiGe at a faster etch rate than it etches Si. The layers 122, 124, 126, and 128 may have a higher etch resistance to the selective etching process than that of the sacrificial layers 121, 123, and 127. In some embodiments, the selective etching includes SiGe oxidation followed by a SiGeOₓ removal. For example, the oxidation may be provided by an oxygen-containing cleaning process and then SiGeOₓ removed by the fluoride-based plasma (e.g., NF₃ plasma) that selectively etches SiGeOₓ at a faster etch rate than it etches Si. Moreover, because oxidation rate of Si is much lower (sometimes 30 times lower) than oxidation rate of SiGe (or Ge), the channel layers 122 and 128 and the semiconductor layer 124 and 126 may not be not significantly etched by the process of laterally recessing the sacrificial layers 121, 123, and 127. As a result, the layers 122, 124, 126, and 128 laterally extend past opposite end surfaces of the sacrificial layers 121, 123, and 127.

In some embodiments, while the interlayer sacrificial layer 125 (referring to FIG. 8) has a higher germanium concentration than that of the sacrificial layers 121, 123, and 127, the interlayer sacrificial layer 125 (referring to FIG. 8) may have a lower etch resistance to the selective etching process than that of the sacrificial layers 121, 123, and 127. For example, the selective etching process may remove an entirety of the interlayer sacrificial layer 125 (referring to FIG. 8), leave an opening O1 between the semiconductor layers 124 and 126.

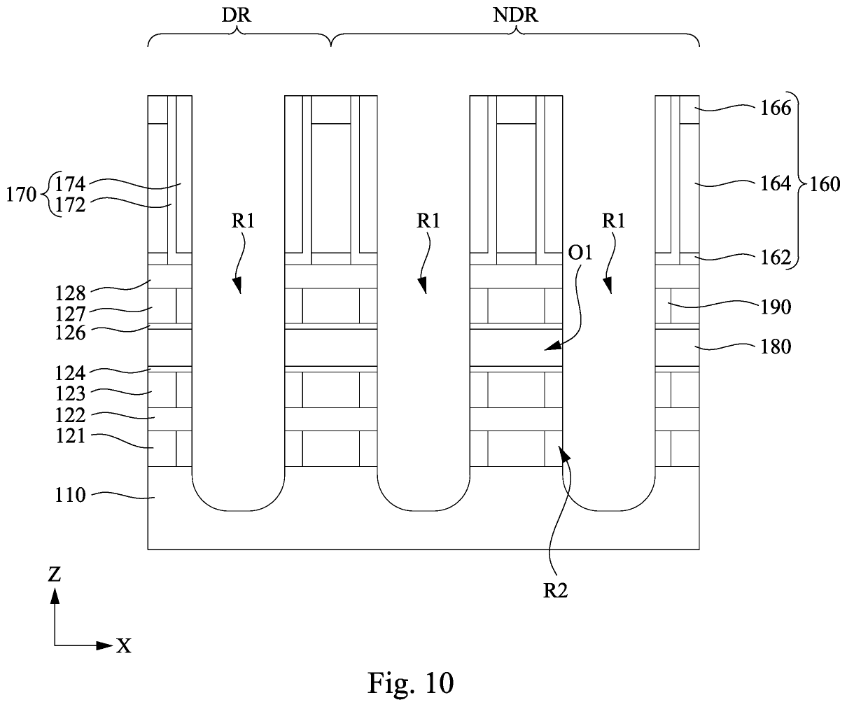

Reference is made to FIG. 10. An isolation layer 180 is formed in the opening O1. In some embodiments, the isolation layer 180 includes low-k dielectric materials, SiN, SiCN, SiOC, SiOCN or the like. Formation of the isolation layer 180 may include suitable CVD, ALD process, the like, or the combination thereof. The isolation layer 180 may serve to isolate a channel for p-type transistor from a channel for n-type transistor. In the example of FIG. 10, sidewalls of the isolation layers 180 are aligned with sidewalls of the channel layers 122 and 128. In the context, the removal of the interlayer sacrificial layer 125 (referring to FIG. 9) and the formation of the isolation layer 180 in combination can be considered as replacing the interlayer sacrificial layer 125 with the isolation layer 180.

Inner spacers 190 are formed in the recesses R2. Stated differently, the inner spacers 190 may be formed on opposite end surfaces of the laterally recessed sacrificial layers 121, 123, and 127. The inner spacers 190 may include a low-k dielectric material, such as SiOₓ, SiON, SiOC, SiN, SiCN, or SiOCN. Formation of the inner spacers 190 may include depositing an inner spacer material layer, followed by an anisotropic etching process to trim the deposited inner spacer material layer. Through the anisotropic etching process, only portions of the deposited inner spacer material layer that fill the lateral/sidewall recesses R2 are left. The inner spacers 190 may include a single layer or multiple layers. The inner spacers 190 may serve to isolate metal gates from source/drain regions formed in subsequent processing. In the example of FIG. 10, sidewalls of the inner spacers 190 are aligned with sidewalls of the channel layers 122 and 128.

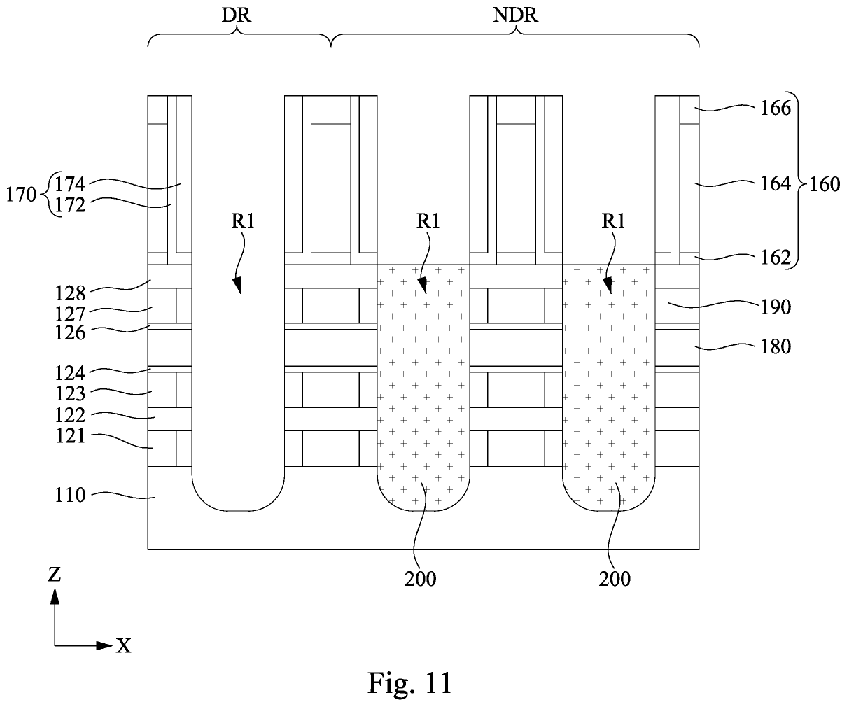

Reference is made to FIG. 11. Source/drain epitaxial structures 200 are formed in the recesses R1 on opposite sides of the channel layers 122 and on opposite sides of the dummy gate structure 160. As aforementioned, the source/drain epitaxial structures 200 are doped to have the second conductive type. The source/drain epitaxial structures 200 may be in contact with the exposed end surfaces of epitaxial layers 122, 124, 126, and 128. In some embodiments, the source/drain epitaxial structures 200 may include Ge, Si, GaAs, AlGaAs, SiGe, GaAsP, SiP, or other suitable material. The source/drain epitaxial structures 200 may be in-situ doped during the epitaxial process by introducing doping species including: p-type dopants, such as boron or BF₂; n-type dopants, such as phosphorus or arsenic; and/or other suitable dopants including combinations thereof. If the source/drain epitaxial structures 200 are not in-situ doped, an implantation process (i.e., a junction implant process) is performed to dope the source/drain epitaxial structures 200. The source/drain epitaxial structures 200 may be formed by performing an epitaxial growth process that provides an epitaxial material on the exposed surfaces of the fins FS. Suitable epitaxial processes include CVD deposition techniques (e.g., vapor-phase epitaxy (VPE) and/or ultra-high vacuum CVD (UHV-CVD)), molecular beam epitaxy, and/or other suitable processes. The epitaxial growth process may use gaseous and/or liquid precursors, which interact with the composition of semiconductor materials of the substrate portion 112 and the epitaxial layers 122, 124, 126, and 128.

In some embodiments, prior to the formation of the source/drain epitaxial structures 200, a patterned mask is formed over the structure of FIG. 10. The patterned mask may cover the region DR and expose a region NDR. The patterned mask may be a photoresist formed by a lithography process (e.g., photolithography or e-beam lithography), which may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the patterned mask may include a hard mask patterned by the photoresist through suitable etching process. With the configuration of the patterned mask, the source/drain epitaxial structures 200 is formed over the region NDR and not over the region DR. After the formation of the source/drain epitaxial structures 200, the patterned mask may be removed by suitable removal process.

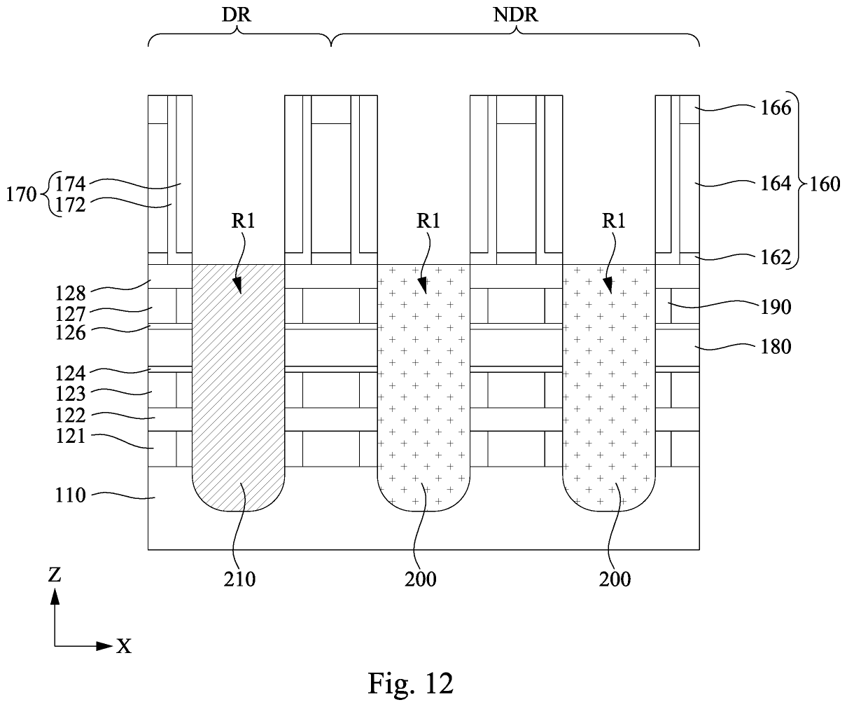

Reference is made to FIG. 12. Source/drain epitaxial structures 210 are formed in the recesses R1 on opposite sides of the channel layers 122 and on opposite sides of the dummy gate structure 160. As aforementioned, the source/drain epitaxial structures 210 are doped to have the first conductive type. The source/drain epitaxial structures 210 may be in contact with the exposed end surfaces of the epitaxial layers 122, 124, 126, and 128. In some embodiments, the source/drain epitaxial structures 210 may include Ge, Si, GaAs, AlGaAs, SiGe, GaAsP, SiP, or other suitable material. The source/drain epitaxial structures 210 may be in-situ doped during the epitaxial process by introducing doping species including: p-type dopants, such as boron or BF₂; n-type dopants, such as phosphorus or arsenic; and/or other suitable dopants including combinations thereof. If the source/drain epitaxial structures 210 are not in-situ doped, an implantation process (i.e., a junction implant process) is performed to dope the source/drain epitaxial structures 210. The source/drain epitaxial structures 210 may be formed by performing an epitaxial growth process that provides an epitaxial material on the exposed surfaces of the fins FS. Suitable epitaxial processes include CVD deposition techniques, molecular beam epitaxy, and/or other suitable processes. The epitaxial growth process may use gaseous and/or liquid precursors, which interact with the composition of semiconductor materials of the substrate portion 112 and the epitaxial layers 122, 124, 126, and 128.

In some embodiments, prior to the formation of the source/drain epitaxial structures 210, a patterned mask is formed over the structure of FIG. 11. The patterned mask may cover the region NDR and expose the region DR. The patterned mask may be a photoresist formed by a lithography process (e.g., photolithography or e-beam lithography), which may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the patterned mask may include a hard mask patterned by the photoresist through suitable etching process. With the configuration of the patterned mask, the source/drain epitaxial structures 210 is formed over the region DR and not over the region NDR. After the formation of the source/drain epitaxial structures 210, the patterned mask may be removed by suitable removal process.

In FIGS. 11 and 12, the source/drain epitaxial structures 210 are formed after the formation of the source/drain epitaxial structures 200. In some alternative embodiments, the source/drain epitaxial structures 210 can be formed prior to the formation of the source/drain epitaxial structures 200.

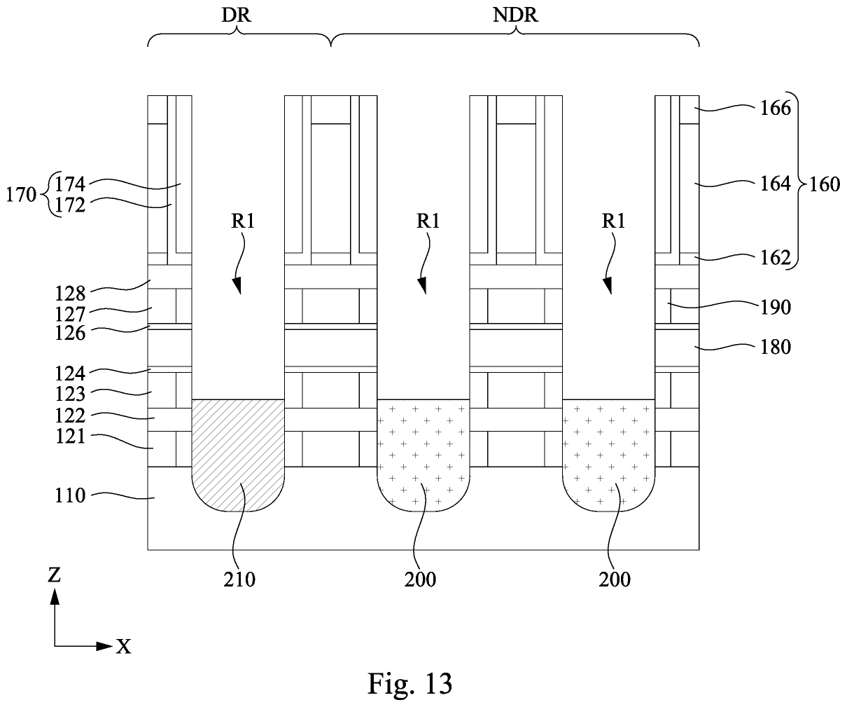

Reference is made to FIG. 13. One or more etching processes may be performed to lower top surfaces of the source/drain epitaxial structures 200 and 210. The resulted source/drain epitaxial structures 200 and 210 have a top surface lower than that of the epitaxial layer 124. The etching process may selectively remove a portion of the source/drain epitaxial structures 200 and 210 but not the dielectric materials of the gate spacers 170, the hard mask 166, the isolation layers 180 and the inner spacers 190. The etching process may be dry etch, wet etch, or the combination thereof.

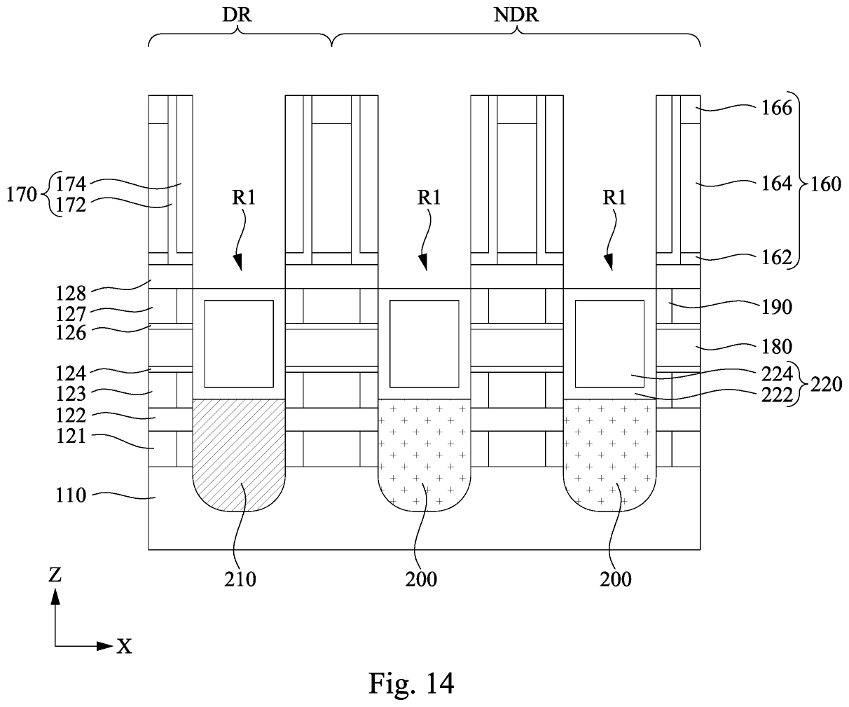

Reference is made to FIG. 14. Dielectric materials 220 are formed into the recesses R2. In some embodiments, the dielectric materials 220 include an etch stop layer (ESL) 222 and an interlayer dielectric (ILD) layer 224. In some examples, the ESL layer 222 includes a silicon nitride layer, silicon oxide layer, a silicon oxynitride layer, and/or other suitable materials having a different etch selectivity than the ILD layer 224. The ESL layer 222 may be formed by plasma-enhanced chemical vapor deposition (PECVD) process and/or other suitable deposition or oxidation processes. In some embodiments, the ILD layer 224 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the ESL layer 222. The ILD layer 224 may be deposited by a CVD process or other suitable deposition technique.

In some embodiments, a first layer of the ESL layer 222 is conformally deposited over the structure of FIG. 12, and the ILD layer 224 is deposited over the ESL layer 222. The ILD layer 224 may be recessed by suitable etching back process. Subsequently, a second layer of the ESL layer 222 is deposited over the etched ILD layer 224, such that the ILD layer 224 is surrounded by the first layer of the ESL layer 222 and the second layer of the ESL layer 222. An etching process may be performed to remove side portions of the second layer of the ESL layer 222, leave the end surface of the channel layer 128 exposed. Through the configuration, the dielectric materials 220 are formed on end surfaces of the epitaxial layers 124 and 126, and expose the end surface of the channel layer 128.

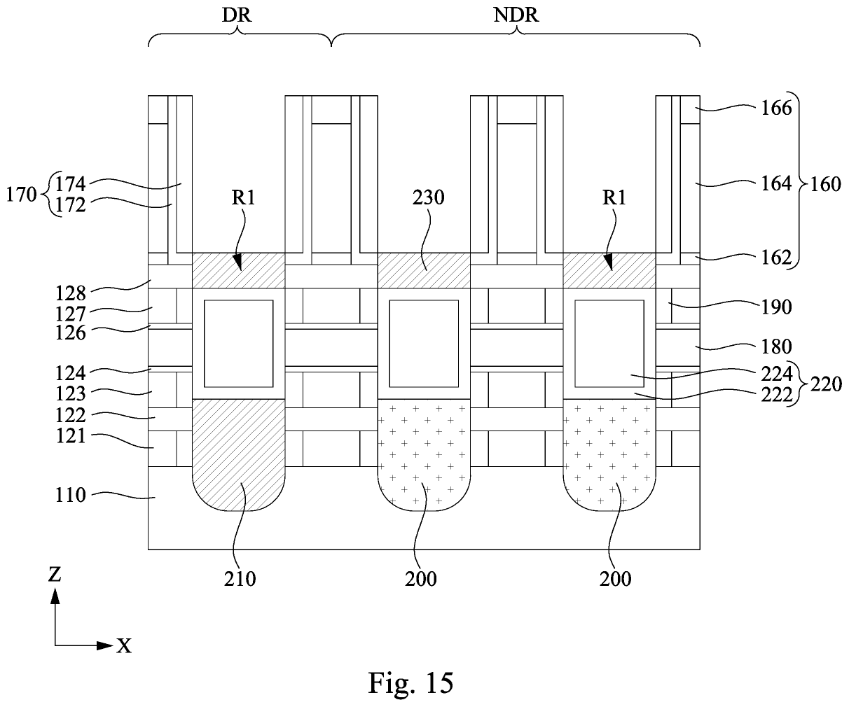

Reference is made to FIG. 15. Source/drain epitaxial structures 230 are formed in the recesses R1 on opposite sides of the channel layers 128 and on opposite sides of the dummy gate structure 160. As aforementioned, the source/drain epitaxial structures 230 are doped to have the first conductive type. The source/drain epitaxial structures 230 may be in contact with the exposed end surfaces of the epitaxial layers 128. In some embodiments, the source/drain epitaxial structures 230 may include Ge, Si, GaAs, AlGaAs, SiGe, GaAsP, SiP, or other suitable material. The source/drain epitaxial structures 230 may be in-situ doped during the epitaxial process by introducing doping species including: p-type dopants, such as boron or BF₂; n-type dopants, such as phosphorus or arsenic; and/or other suitable dopants including combinations thereof. If the source/drain epitaxial structures 230 are not in-situ doped, an implantation process (i.e., a junction implant process) is performed to dope the source/drain epitaxial structures 230. The source/drain epitaxial structures 230 may be formed by performing an epitaxial growth process that provides an epitaxial material on the exposed surfaces of the fins FS. Suitable epitaxial processes include CVD deposition techniques, molecular beam epitaxy, and/or other suitable processes. The epitaxial growth process may use gaseous and/or liquid precursors, which interact with the composition of semiconductor materials of the channel layers 128.

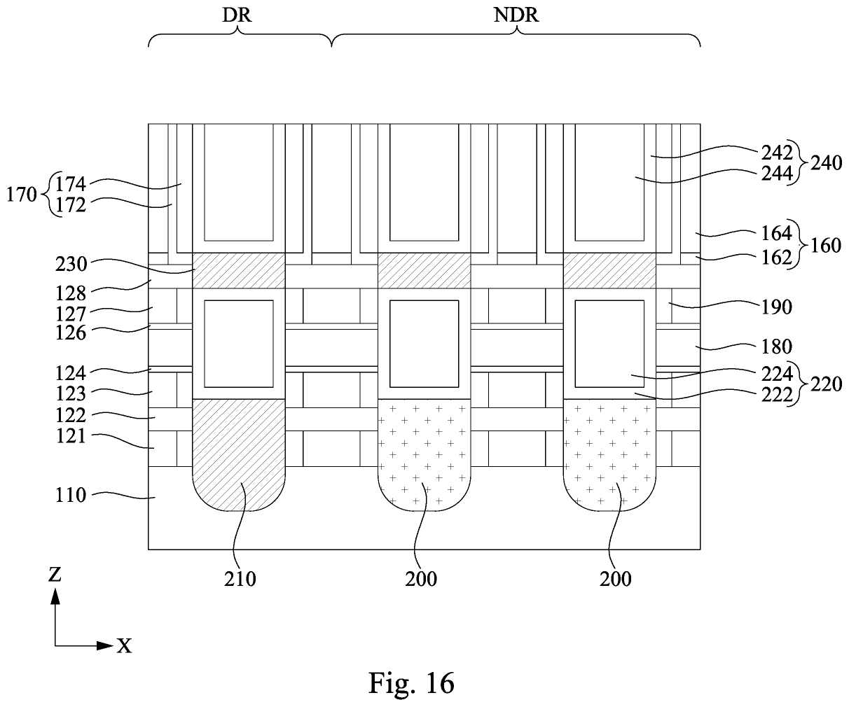

Reference is made to FIG. 16. Dielectric material 240 are formed over the substrate 110 and filling the space between the dummy gate structures 160. In some embodiments, the dielectric material 240 includes a contact etch stop layer (CESL) 242 and an interlayer dielectric (ILD) layer 244 formed in sequence. In some examples, the CESL layer 242 includes a silicon nitride layer, silicon oxide layer, a silicon oxynitride layer, and/or other suitable materials having a different etch selectivity than the ILD layer 244. The CESL layer 242 may be formed by plasma-enhanced chemical vapor deposition (PECVD) process and/or other suitable deposition or oxidation processes. The ILD layer 244 is then deposited over the CESL layer 242. In some embodiments, the ILD layer 244 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the CESL layer 242. The ILD layer 244 may be deposited by a CVD process or other suitable deposition technique. In some embodiments, after formation of the ILD layer 244, the semiconductor device may be subject to a high thermal budget process to anneal the ILD layer 244. After depositing the ILD layer 244, a planarization process may be performed to remove excessive materials of the ILD layer 244. For example, a planarization process includes a chemical mechanical polish (CMP) process which removes portions of the ILD layer 244 and the CESL layer 242 overlying the dummy gate structures 160 and planarizes a top surface of the integrated circuit device. The planarization process may also remove the hard mask 166 (referring to FIG. 15), which leaves the dummy gate electrode 164 exposed.

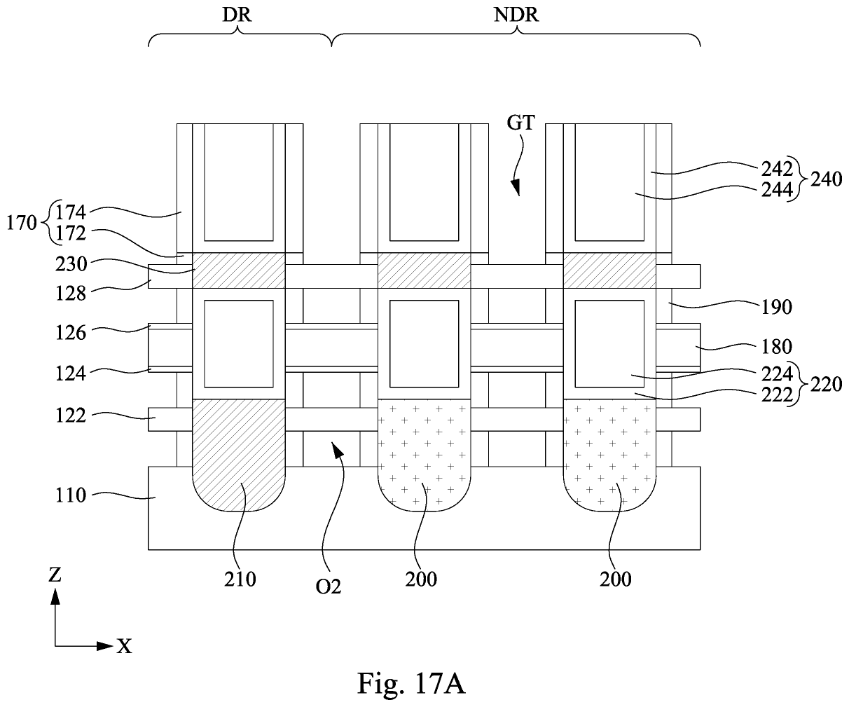

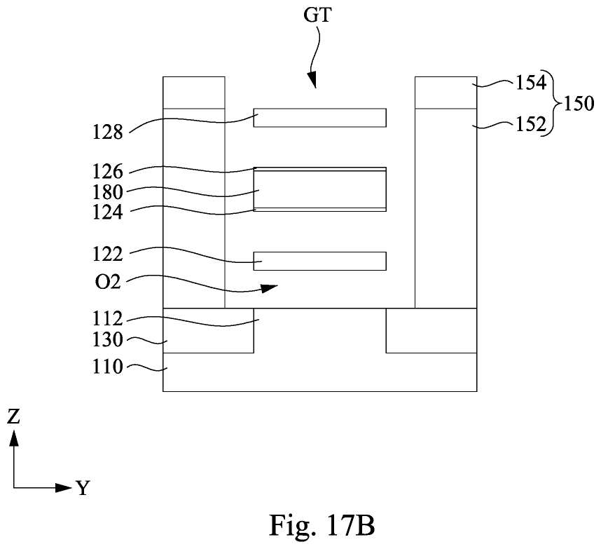

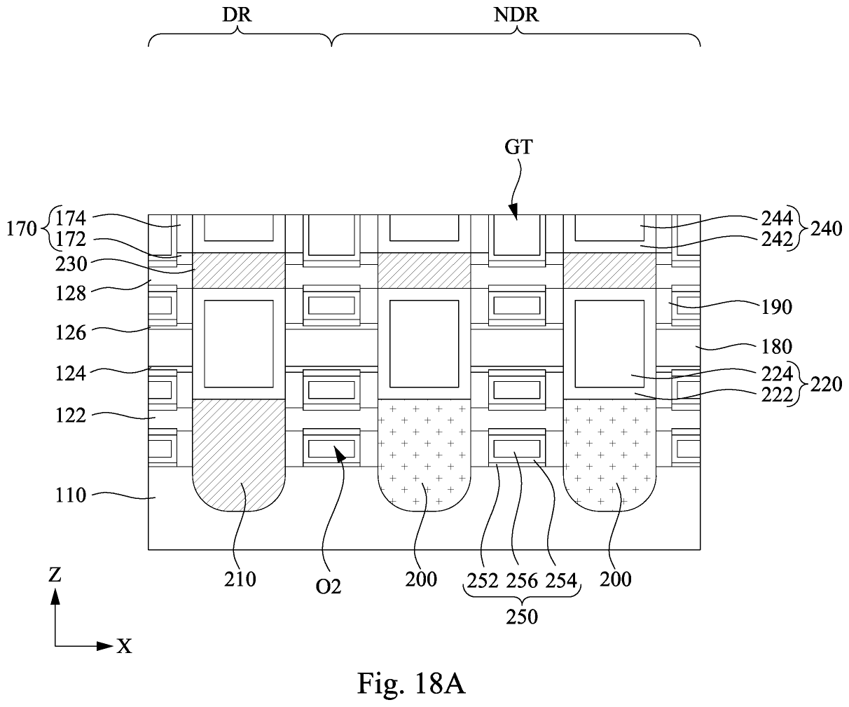

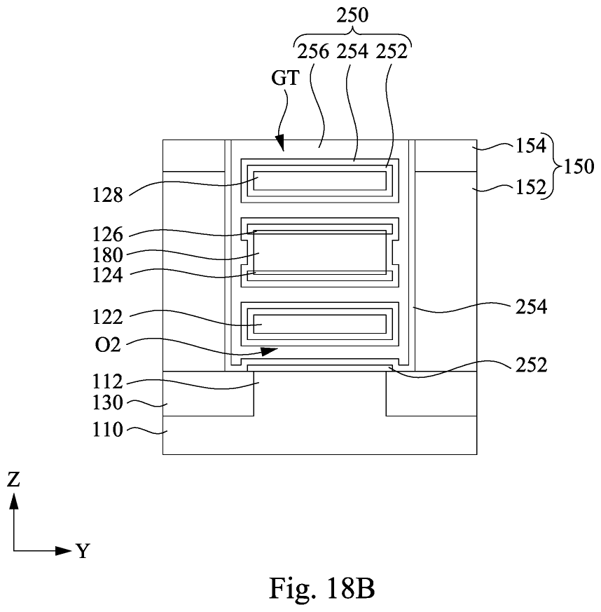

Reference is made to FIGS. 17A-18B. The dummy gate structure 160, the sacrificial layer 121, 123, and 127 (referring to FIG. 16), and the cladding layer 140 (referring to FIG. 7B) are replaced with a high-k/metal gate structure 250. In FIGS. 17A and 17B, the dummy gate structures 160 (referring to FIG. 16) are removed, followed by removing the sacrificial layers 121, 123, and 127 (referring to FIG. 16) and the cladding layer 140 (referring to FIG. 7B). In the illustrated embodiments, the dummy gate structures 160 (referring to FIG. 16) are removed by using a selective etching process (e.g., selective dry etching, selective wet etching, or a combination thereof) that etches the materials in dummy gate structures 160 (referring to FIG. 16) at a faster etch rate than it etches other materials (e.g., gate spacers 170 and/or the dielectric material 240), thus resulting in gate trenches GT between corresponding gate spacers 170, with the sacrificial layers 121, 123, and 127 (referring to FIG. 16) and the cladding layer 140 (referring to FIG. 7B) exposed in the gate trenches GT. Subsequently, the sacrificial layers 121, 123, and 127 (referring to FIG. 16) and the cladding layer 140 (referring to FIG. 7B) in the gate trenches GT are etched by using another selective etching process that etches the sacrificial layers 121, 123, and 127 (referring to FIG. 16) and the cladding layer 140 (referring to FIG. 7B) at a faster etch rate than it etches the layers 122, 124, 126, 128, thus forming openings/spaces O2 between neighboring channel layers 122, 124, 126, 128. The openings/spaces O2 may expose the sidewalls of the inner spacers 190. In this way, the channel layers 128 become nanosheets suspended over the substrate 110 and between the source/drain epitaxial structures 230, and the channel layers 122 and become nanosheets suspended over the substrate 110 and between the source/drain epitaxial structures 200 or between the source/drain epitaxial structures 200 and 210. This step is also called a channel release process. At this interim processing step, the openings/spaces O2 surrounding the nanosheets 122 and 128 may be filled with ambient environment conditions (e.g., air, nitrogen, etc). In some embodiments, the nanosheets 122 and 128 can be interchangeably referred to as nanowires, nanoslabs and nanorings, depending on their geometry. For example, in some other embodiments, the channel layers 122 and 128 may be trimmed to have a substantial rounded shape (i.e., cylindrical) due to the selective etching process for completely removing the sacrificial layers 121, 123, and 127 (referring to FIG. 16). In that case, the resultant channel layers 122 and 128 can be called nanowires.

In some embodiments, the sacrificial layers 121, 123, and 127 (referring to FIG. 16) and the cladding layer 140 (referring to FIG. 7B) are removed by using a selective dry etching process. In some embodiments, the sacrificial layers 121, 123, and 127 (referring to FIG. 16) and the cladding layer 140 (referring to FIG. 7B) are SiGe and the channel layers 224 are silicon allowing for the selective removal of the sacrificial layers 121, 123, and 127 (referring to FIG. 16) and the cladding layer 140 (referring to FIG. 7B). In some embodiments, the selective dry etching may use chloride-based gases, such as CF₄, C₄F₈, the like, or the combination thereof. In some embodiments, the selective removal includes SiGe oxidation followed by a SiGeOₓ removal. For example, the oxidation may be provided by O₂ plasma and then SiGeOₓ removed by the chloride-based plasma (e.g., CF₄/C₄F₈ plasma) that selectively etches SiGeOₓ at a faster etch rate than it etches Si, and stops on SiGe. The steps of SiGe oxidation and SiGeOₓ removal may be repeated until the sacrificial layers 121, 123, and 127 (referring to FIG. 16) and the cladding layer 140 (referring to FIG. 7B) is removed. Moreover, because oxidation rate of Si is much lower (sometimes 30 times lower) than oxidation rate of SiGe, the channel layers 122 and 128 and the semiconductor layer 124 and 126 may remain substantially intact during the channel release process.

Reference is made to FIGS. 18A and 18B. Replacement gate structures 250 are respectively formed in the gate trenches GT to surround each of the nanosheets 122 and 128 suspended in the gate trenches GT. The gate structures 250 may be final gates of GAA FETs. The final gate structure may be a high-k/metal gate stack, however other compositions are possible. In some embodiments, each of the gate structures 250 forms the gate associated with the multi-channels provided by the plurality of nanosheets 122 and 128. For example, the high-k/metal gate structures 250 are formed within the openings/spaces O2 provided by the release of nanosheets 122 and 128. The high-k/metal gate structures 250 may be between the layers 122, 124, 126, and 128 and surrounded by the inner spacers 190.

In various embodiments, the high-k/metal gate structure 250 includes a gate dielectric layer formed around the nanosheets 122 and 128 and a gate metal layer 256 formed around the dielectric layer and filling a remainder of gate trenches GT. Formation of the high-k/metal gate structures 250 may include one or more deposition processes to form various gate materials, followed by a CMP processes to remove excessive gate materials, resulting in the high-k/metal gate structures 250 having top surfaces level with a top surface of the dielectric material 240. Thus, transistors (e.g., GAA FET) are formed, and the high-k/metal gate structure 250 surrounds each of the nanosheets 122 and 128, and thus is referred to as a gate of the transistors (e.g., GAA FET).

The gate dielectric layer may include an interfacial layer 252 and a high-k gate dielectric layer 254 over the interfacial layer 252. In some embodiments, the interfacial layer 252 is silicon oxide formed on exposed surfaces of semiconductor materials in the gate trenches GT by using, for example, thermal oxidation, chemical oxidation, wet oxidation or the like. As a result, surface portions of the layers 122, 124, 126, and 128, and the substrate 110 exposed in the gate trenches GT are oxidized into silicon oxide to form interfacial layer 252. In some embodiments, the high-k gate dielectric layer 254 includes dielectric materials such as hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO; HZO), lanthanum oxide (LaO), zirconium oxide (ZrO), titanium oxide (TiO₂), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), the like, or combinations thereof.

In some embodiments, the gate metal layer 256 includes one or more metal layers. For example, the gate metal layer 256 may include one or more work function metal layers stacked one over another and a fill metal filling up a remainder of gate trenches GT. The one or more work function metal layers in the gate metal layer 256 provide a suitable work function for the high-k/metal gate structures GS. For an n-type GAA FET, the gate metal layer 256 may include one or more n-type work function metal (N-metal) layers. The n-type work function metal may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AIC)), aluminides, titanium nitride (TiN), tungsten (W), and/or other suitable materials. On the other hand, for a p-type GAA FET, the gate metal layer 256 may include one or more p-type work function metal (P-metal) layers. The p-type work function metal may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. In some embodiments, the fill metal in the gate metal layer 256 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

Reference is made to FIGS. 19A and 19B. An ESL layer 260 and an interlayer dielectric layer 270 are formed over the structure of FIGS. 18A and 18B. In some examples, the ESL layer 260 includes a silicon nitride layer, silicon oxide layer, a silicon oxynitride layer, and/or other suitable materials having a different etch selectivity than the ILD layer 270. The ESL layer 260 may be formed by plasma-enhanced chemical vapor deposition (PECVD) process and/or other suitable deposition or oxidation processes. In some embodiments, the ILD layer 270 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the ESL layer 260. The ILD layer 270 may be deposited by a CVD process or other suitable deposition technique.

Frontside contact plugs 300BLB, 300QB, 300Vss are formed for providing electrical connection to the source/drain epitaxial structures 200, 210, and 230. For example, one or more first etching processes are performed to first form contact openings by removing the ILD layer 270, the ESL layer 260, the ILD layer 244 (referring to FIG. 18A), and a bottom portion of the CESL 242 (referring to FIG. 18A). The contact openings may extend through the ILD layer 270, the ESL layer 260, and the CESL 242, and expose top surfaces of the source/drain epitaxial structures 230. Subsequently, one or more second etching processes are performed to deepen some of the contact openings by removing the source/drain epitaxial structure 230 and the dielectric materials 220. The deepened contact openings may extend through the ILD layer 270, the ESL layer 260, the CESL 242, the source/drain epitaxial structure 230, and the dielectric materials 220, and exposes top surfaces of the source/drain epitaxial structure 200/210.

Metal alloy layers 292P, 292N, 294N are respectively formed on portions of the source/drain epitaxial structures 200, 210, and 230 exposed by the contact openings. The metal alloy layers 292P, 292N, 294N, which may be silicide layers, are respectively formed in the contact openings and over the exposed frontside of the source/drain epitaxial structures 200, 210, and 230, by a self-aligned silicide (salicide) process. The silicide process converts the surface portions of the source/drain epitaxial structures 200, 210, and 230 into the silicide contacts. Silicide processing involves deposition of a metal that undergoes a silicidation reaction with silicon (Si). In order to form silicide contacts on the source/drain epitaxial structures 200, 210, and 230, a metal material is blanket deposited on the exposed frontside of the source/drain epitaxial structures 200, 210, and 230. After heating the wafer to a temperature at which the metal reacts with the silicon of the source/drain epitaxial structures 200, 210, and 230 to form contacts, unreacted metal is removed. The silicide contacts remain over the frontside of the source/drain epitaxial structures 200, 210, and 230, while unreacted metal is removed from other areas. The silicide layer may include a material selected from titanium silicide, cobalt silicide, nickel silicide, platinum silicide, nickel platinum silicide, erbium silicide, palladium silicide, combinations thereof, or other suitable materials. In some embodiments, the metal alloy layer 292P, 292N, 294N may include germanium.

Frontside contact plugs 300BLB, 300BL, 300Q, 300QB, 300Vss are then formed. Each of the contact plugs 300BLB and 300BL is formed in the deepened contact opening and in contact with the metal alloy layers 292N and 294N. As such, each of the contact plug 300BLB and 300BL is electrically connected to the source/drain epitaxial structures 210 and 230. Each of the contact plug 300QB and 300Q is formed in the deepened contact opening and in contact with the metal alloy layers 292P and 294N. As such, each of the contact plug 300QB and 300Q is electrically connected to the source/drain epitaxial structures 200 and 230. Each of the contact plugs 300Vss is formed in the contact opening (not deepened) and in contact with the metal alloy layer 294N. As such, each of the contact plug 300Vss is electrically connected to the source/drain epitaxial structure 230. Each of the contact plugs 300BLB, 300BL, 300Q, 300QB, 300Vss may include a barrier layer 302 and a fill metal 304. The barrier layer 302 may be made of TiN, TaN, or combinations thereof. In some embodiments, the fill metal 304 may be made of metal, such as W, Co, Ru, Al, Cu, or other suitable materials. After the deposition of the contact materials, a planarization process, such as a chemical mechanical polish (CMP) process, may be then performed.

An ESL layer 310 and an interlayer dielectric layer 320 are formed over the contact plugs 300BLB. 300QB, and 300Vss. In some examples, the ESL layer 310 includes a silicon nitride layer, silicon oxide layer, a silicon oxynitride layer, and/or other suitable materials having a different etch selectivity than the ILD layer 320. The ESL layer 310 may be formed by plasma-enhanced chemical vapor deposition (PECVD) process and/or other suitable deposition or oxidation processes. In some embodiments, the ILD layer 320 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the ESL layer 310. The ILD layer 320 may be deposited by a CVD process or other suitable deposition technique.

Conductive vias 330 are formed through the interlayer dielectric layer 320 and the ESL layer 310. In the illustrated embodiments, the conductive vias 330 are formed for providing electrical connection to the contact plugs 300BLB and 300BL. In some embodiments, as illustrated in FIG. 2A, plural conductive vias 330 are formed for providing electrical connection to the contact plugs 300BLB and 300BL, the word lines WL, the contact plug 300Vss. For example, as illustrated in FIGS. 1 and 2A, a first one of conductive via 330 is formed for providing electrical connection between the contact plug 300BLB and the bit line BLB, a second one of conductive via 330 is formed for providing electrical connection between the contact plug 300BL and the bit line BL, a third one and a fourth one of conductive via 330 are formed for providing electrical connection between the gate structure 250 and the word line WL, a fifth one and a sixth of conductive via 330 are formed for providing electrical connection between the contact plug 300Vss and the power supply voltage node Vss.

A front-side multilayer interconnection (MLI) structure FMLI may be formed over the substrate 110. The front-side MLI structure FMLI may include a plurality of front-side metallization layers. The number of front-side metallization layers may vary according to design specifications of the integrated circuit. The front-side metallization layers each comprise a front-side inter-metal dielectric (IMD) layer, one or more horizontal interconnects, such as front-side metal lines, respectively extending horizontally or laterally in the front-side IMD layer, and vertical interconnects, such as front-side conductive vias, respectively extending vertically in the front-side IMD layer.

Reference is made to FIGS. 20A and 20B. Backside contact plugs 360Vdd, 360Q, 360QB, 360DM are formed for providing electrical connection to the source/drain epitaxial structures 200 and 210. For example, one or more etching processes are performed to form contact openings by removing portions of the substrate 110. The contact openings may expose bottom surfaces of the source/drain epitaxial structures 200 and 210. Metal alloy layers 350P and 350N are respectively formed on portions of the source/drain epitaxial structures 200 and 210 exposed by the contact openings. The metal alloy layers 350P and 350N, which may be silicide layers, are respectively formed in the contact openings and over the exposed backside of the source/drain epitaxial structures 200 and 210 by a self-aligned silicide (salicide) process. The silicide process converts the surface portions of the source/drain epitaxial structures 200 and 210 into the silicide contacts. Silicide processing involves deposition of a metal that undergoes a silicidation reaction with silicon (Si). In order to form silicide contacts on the source/drain epitaxial structures 200 and 210, a metal material is blanket deposited on the exposed backside of the source/drain epitaxial structures 200 and 210. After heating the wafer to a temperature at which the metal reacts with the silicon of the source/drain epitaxial structures 200 and 210 to form contacts, unreacted metal is removed. The silicide contacts remain over the backside of the source/drain epitaxial structures 200 and 210, while unreacted metal is removed from other areas. The silicide layer may include a material selected from titanium silicide, cobalt silicide, nickel silicide, platinum silicide, nickel platinum silicide, erbium silicide, palladium silicide, combinations thereof, or other suitable materials. In some embodiments, the metal alloy layer 350P and 350N may include germanium.

Backside contact plugs 360Vdd, 360Q, 360QB, 360DM are then formed. Each of the contact plugs 360Vdd, 360Q, and 360QB is formed in the contact opening and in contact with the metal alloy layers 350P. As such, each of the contact plug 360Vdd, 360Q, and 360QB is electrically connected to the source/drain epitaxial structures 200. The contact plug 360DM is formed for addressing loading issues during fabrication process. The contact plug 360DM is not designed for providing electrical connection, can be omitted in some embodiments. In the illustrated embodiments, the contact plug 360DM is formed in the contact opening and in contact with the metal alloy layers 350N, and may be electrically connected to the source/drain epitaxial structures 210. Each of the contact plugs 360Vdd, 360Q, 360QB, 360DM may include a barrier layer 362 and a fill metal 364. The barrier layer 362 may be made of TiN, TaN, or combinations thereof. In some embodiments, the fill metal 364 may be made of metal, such as W, Co, Ru, Al, Cu, or other suitable materials. After the deposition of the contact materials, a planarization process, such as a chemical mechanical polish (CMP) process, may be then performed. In some embodiments after the formation of the backside contact plugs 360Vdd, 360Q, 360QB, 360DM, the substrate 110 (referring to FIGS. 19A and 19B) may be replaced with suitable dielectric materials, such as silicon oxide, silicon nitride, the like, or the combination thereof. For example, the substrate 110 removed by suitable etching process to expose sidewalls of the backside contact plugs 360Vdd, 360Q, 360QB, 360DM, and a dielectric structure 340 including a dielectric layer 342 (e.g., silicon nitride) and a dielectric filling material 344 (e.g., silicon oxide) are formed around the backside contact plugs 360Vdd, 360Q, 360QB, 360DM.

An ESL layer 370 and an interlayer dielectric layer 380 are formed over the contact plugs 360Vdd, 360Q, 360QB, 360DM. In some examples, the ESL layer 370 includes a silicon nitride layer, silicon oxide layer, a silicon oxynitride layer, and/or other suitable materials having a different etch selectivity than the ILD layer 380. The ESL layer 370 may be formed by plasma-enhanced chemical vapor deposition (PECVD) process and/or other suitable deposition or oxidation processes. In some embodiments, the ILD layer 380 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the ESL layer 370. The ILD layer 380 may be deposited by a CVD process or other suitable deposition technique.

Conductive feature 390 is formed through the interlayer dielectric layer 380 and the ESL layer 370. In the illustrated embodiments, the conductive feature 390 is formed for providing electrical connection between the contact plugs 360Q and one of the gate structures 250. In some embodiments, as illustrated in FIG. 2B, one of the conductive features 390 is formed for providing electrical connection between the contact plugs 360Q and the gate structure 250 of the transistor PU2, and another one of the conductive features 390 is formed for providing electrical connection between the contact plugs 360QB and the gate structure 250 of the transistor PU1.

A back-side multilayer interconnection (MLI) structure BMLI may be formed. The back-side MLI structure BMLI may include a plurality of back-side metallization layers. The number of back-side metallization layers may vary according to design specifications of the integrated circuit. The back-side metallization layers each comprise a back-side inter-metal dielectric (IMD) layer, one or more horizontal interconnects, such as back-side metal lines, respectively extending horizontally or laterally in the back-side IMD layer, and vertical interconnects, such as back-side conductive vias, respectively extending vertically in the back-side IMD layer.

Through the configuration, pull-up transistors PU1 and PU2, pull-down transistors PD1 and PD2, pass-gate transistors PG1 and PG2, and the diodes D1 and D2 are formed. Each of the pull-down transistors PD1 and PD2 and pass-gate transistors PG1 and PG2 includes a channel layer 128, two source/drain epitaxial structures 230 on opposite sides of the channel layer 128, and a gate structure 250 surrounding the channel layer 128. Adjacent two of the pull-down transistors PD1 and PD2 and pass-gate transistors PG1 and PG2 may share a same source/drain epitaxial structure 230. Each of the pull-up transistors PU1 and PU2 includes a channel layer 122, two source/drain epitaxial structures 200 on opposite sides of the channel layer 122, and a gate structure 250 surrounding the channel layer 128. The pull-up transistors PU1 and PU2 may share the same gate structure 250 with the pull-down transistors PD1 and PD2, respectively. For example, the gate structure 250 continuously surrounds the channel layers 121 and 128 in FIG. 18B. Each of the diodes D1 and D2 includes a source/drain epitaxial structure 210, an intrinsic semiconductor layer 122, and a source/drain epitaxial structure 200. The source/drain epitaxial structure 210, the intrinsic semiconductor layer 122, and the source/drain epitaxial structure 200 may form a lateral PIN junction. In the context, the source/drain epitaxial structures 200, 210, and 230 may also be referred to as source/drain epitaxial features.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that diodes are added to the circuit diagram of the SRAM cell, thereby increasing a current from the storage data node to the bit line during a writing operation, which in turn will improve CFET SRAM writability. Another advantage is that the diodes are created beneath a pass gate transistor, such that it takes 4T footprint to accommodate 6T SRAM and the diodes without occupying additional area.

According to some embodiments of the present disclosure, an integrated circuit device includes a first semiconductor layer and a second semiconductor layer above the first semiconductor layer, wherein the first and second semiconductor layers are vertically spaced apart from each other; a first source/drain epitaxial feature on a first side of the first semiconductor layer when viewed from top; a second source/drain epitaxial feature on a second side of the first semiconductor layer when viewed from top; a third source/drain epitaxial feature above the first source/drain epitaxial feature, wherein the third source/drain epitaxial feature is on a first side of the second semiconductor layer when viewed from top; and a fourth source/drain epitaxial feature above the second source/drain epitaxial feature, wherein the fourth source/drain epitaxial feature is on a second side of the second semiconductor layer when viewed from top, wherein the first, third, and fourth source/drain epitaxial features have a first conductive type, and the second source/drain epitaxial feature has a second conductive type opposite to the first conductive type.

According to some embodiments of the present disclosure, an integrated circuit device includes a first pull-up transistor and a second pull-up transistor; a first pull-down transistor and a second pull-down transistor that respectively form cross-latched first and second inverters with the first pull-up transistor and the second pull-up transistor; a first bit line; a second bit line; a first pass-gate transistor electrically coupled between the first bit line and drains of the first pull-up transistor and the first pull-down transistor; a second pass-gate transistor electrically coupled between the second bit line and drains of the second pull-up transistor and the second pull-down transistor; and a first diode electrically coupled between the first bit line and the drains of the first pull-up transistor and the first pull-down transistor.

According to some embodiments of the present disclosure, a method includes forming an epitaxial stack over a substrate, the epitaxial stack comprising a first semiconductor layer and a second semiconductor layer; forming a first source/drain epitaxial feature on a first side of the first semiconductor layer; forming a second source/drain epitaxial feature on a second side of the first semiconductor layer; forming a third source/drain epitaxial feature on a first side of the second semiconductor layer; and forming a fourth source/drain epitaxial feature on a second side of the second semiconductor layer, wherein the first, third, and fourth source/drain epitaxial features have a first conductive type, and the second source/drain epitaxial feature has a second conductive type opposite to the first conductive type.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit device, comprising:
a first semiconductor layer and a second semiconductor layer above the first semiconductor layer, wherein the first and second semiconductor layers are vertically spaced apart from each other;
a first source/drain epitaxial feature on a first side of the first semiconductor layer when viewed from top;
a second source/drain epitaxial feature on a second side of the first semiconductor layer when viewed from top;
a third source/drain epitaxial feature above the first source/drain epitaxial feature, wherein the third source/drain epitaxial feature is on a first side of the second semiconductor layer when viewed from top; and
a fourth source/drain epitaxial feature above the second source/drain epitaxial feature, wherein the fourth source/drain epitaxial feature is on a second side of the second semiconductor layer when viewed from top, wherein the first, third, and fourth source/drain epitaxial features have a first conductive type, and the second source/drain epitaxial feature has a second conductive type opposite to the first conductive type.

2. The integrated circuit device of claim 1, further comprising:
a gate structure continuously surrounds the first semiconductor layer and the second semiconductor layer.

3. The integrated circuit device of claim 1, further comprising:
a second contact plug electrically connecting the fourth source/drain epitaxial feature to the second source/drain epitaxial feature.

4. The integrated circuit device of claim 3, wherein the fourth source/drain epitaxial feature surrounds the second contact plug.

5. The integrated circuit device of claim 1, further comprising:
a first contact plug electrically connecting the third source/drain epitaxial feature to the first source/drain epitaxial feature.

6. The integrated circuit device of claim 5, wherein the third source/drain epitaxial feature surrounds the first contact plug.

7. The integrated circuit device of claim 1, further comprising:
an isolation layer between the first semiconductor layer and the second semiconductor layer, wherein a top surface of the second source/drain epitaxial feature is lower than a bottom surface of the isolation layer.

8. The integrated circuit device of claim 7, wherein a bottom surface of the fourth source/drain epitaxial feature is higher than a top surface of the isolation layer.

9. The integrated circuit device of claim 1, further comprising:
a backside contact plug over a backside of the first source/drain epitaxial feature.

10. The integrated circuit device of claim 1, further comprising:
a dummy backside contact plug over a backside of the second source/drain epitaxial feature.

11. An integrated circuit device, comprising:
a first pull-up transistor and a second pull-up transistor;
a first pull-down transistor and a second pull-down transistor that respectively form cross-latched first and second inverters with the first pull-up transistor and the second pull-up transistor;
a first bit line;
a second bit line;
a first pass-gate transistor electrically coupled between the first bit line and drains of the first pull-up transistor and the first pull-down transistor;
a second pass-gate transistor electrically coupled between the second bit line and drains of the second pull-up transistor and the second pull-down transistor; and
a first diode electrically coupled between the first bit line and the drains of the first pull-up transistor and the first pull-down transistor.

12. The integrated circuit device of claim 11, wherein the first pull-up transistor is vertically overlapping the first pull-down transistor, and the second pull-up transistor is vertically overlapping the second pull-down transistor.

13. The integrated circuit device of claim 11, wherein the first diode is vertically overlapping the first pass-gate transistor.

14. The integrated circuit device of claim 11, wherein the first diode comprises:
a n-type source/drain epitaxial feature electrically coupled to the first bit line; and
a p-type source/drain epitaxial feature electrically coupled to the drains of the first pull-up transistor and the first pull-down transistor.

15. The integrated circuit device of claim 14, wherein the first diode further comprises:
an intrinsic semiconductor layer laterally between the n-type source/drain epitaxial feature and the p-type source/drain epitaxial feature.

16. The integrated circuit device of claim 11, further comprising:
a second diode electrically coupled between the second bit line and the drains of the second pull-up transistor and the second pull-down transistor.

17. The integrated circuit device of claim 16, wherein the second diode is vertically overlapping the second pass-gate transistor.

18. A method, comprising:
forming an epitaxial stack over a substrate, the epitaxial stack comprising a first semiconductor layer and a second semiconductor layer;
forming a first source/drain epitaxial feature on a first side of the first semiconductor layer;
forming a second source/drain epitaxial feature on a second side of the first semiconductor layer;
forming a third source/drain epitaxial feature on a first side of the second semiconductor layer; and
forming a fourth source/drain epitaxial feature on a second side of the second semiconductor layer, wherein the first, third, and fourth source/drain epitaxial features have a first conductive type, and the second source/drain epitaxial feature has a second conductive type opposite to the first conductive type.

19. The method of claim 18, wherein the epitaxial stack comprises a first sacrificial layer, a second sacrificial layer, and a third sacrificial layer between the first semiconductor layer and the second semiconductor layer, the method further comprises:
replacing the second sacrificial layer with an isolation layer; and
replacing the first and third sacrificial layers with a metal gate structure.

20. The method of claim 18, further comprising:
after forming the first and second source/drain epitaxial features, prior to forming the third and fourth source/drain epitaxial features, forming a plurality of dielectric materials over the first and second source/drain epitaxial features.
